(19) United States
(12) Patent Application Publication
(10) Pub. No.: US 2026/0223454 A1
(43) Pub. Date: Jul. 30, 2026

(54) ARRAY SUBSTRATE AND METHOD FOR MANUFACTURING THE SAME, AND DISPLAY PANEL

(71) Applicant: Guangzhou China Star Optoelectronics Semiconductor Display Technology Co., LTd., Guangzhou (CN)

(72) Inventors: Xiaolin YAN, Guangzhou (CN); Jun ZHAO, Guangzhou (CN); Bin ZHAO, Guangzhou (CN); Weiran CAO, Guangzhou (CN); Mingjiue YU, Guangzhou (CN); Xiaoxing ZHANG, Guangzhou (CN); Yuanjun HSU, Guangzhou (CN)

(73) Assignee: Guangzhou China Star Optoelectronics Semiconductor Display Technology Co., LTd., Guangzhou (CN)

(21) Appl. No.: 19/224,793

(22) Filed: May 31, 2025

(30) Foreign Application Priority Data
Jan. 24, 2025 (CN) 202510122941.0

(51) Int. Cl. H10D 86/40; H10D 86/01; H10D 86/60

(52) U.S. Cl. CPC H10D 86/423; H10D 86/0221; H10D 86/60

(57) ABSTRACT

An array substrate, a method for manufacturing the same, and a display panel are provided. The array substrate includes a pixel arrangement area and a non-pixel arrangement area adjacent to the pixel arrangement area, and further includes a first transistor disposed in the pixel arrangement area and a second transistor disposed in the non-pixel arrangement area, where the first transistor includes a first active portion, the second transistor includes a second active portion, the first active portion includes a first metal oxide material, the second active portion includes a second metal oxide material different from the first metal oxide material, and a mobility of the second active portion is greater than a mobility of the first active portion.

### CROSS-REFERENCE TO RELATED APPLICATION

This application claims priority to and the benefit of Chinese Patent Application No. 202510122941.0, filed on January 24, 2025, the disclosure of which is incorporated herein by reference in its entirety.

### TECHNICAL FIELD

The present disclosure relates to the field of display, and in particular, to an array substrate and a method for manufacturing the same, and a display panel.

### BACKGROUND

With the development of display technology, people have increasingly high demands for the narrow bezel of a display. In order to reduce the width of the bezel of the display, in the prior art, a gate driver on array (GOA) is prepared on a thin film transistor (TFT) array substrate, so that the amount of manufacturing procedures can be reduced, and thus the cost can be reduced. Since a gate driver chip (an integrate circuit (IC)) is not required, the narrow bezel can be achieved, and the integration degree of the TFT array substrate can be improved.

In the display, a TFT of a pixel unit in a display area and a TFT of the GOA in a non-display area are generally made of the same active material, resulting in the inability to simultaneously satisfy the stability of the TFT of the pixel unit and the charging efficiency of the TFT of the GOA.

### SUMMARY

Some embodiments of the present disclosure provide an array substrate including a pixel arrangement area and a non-pixel arrangement area adjacent to the pixel arrangement area, and the array substrate further includes a first transistor disposed in the pixel arrangement area and a second transistor disposed in the non-pixel arrangement area;

where the first transistor includes a first active portion, the second transistor includes a second active portion, the first active portion includes a first metal oxide material, the second active portion includes a second metal oxide material different from the first metal oxide material, and a mobility of the second active portion is greater than a mobility of the first active portion.

Some embodiments of the present disclosure further provide a method for manufacturing an array substrate, the array substrate includes a pixel arrangement area and a non-pixel arrangement area adjacent to the pixel arrangement area, and the method for manufacturing the array substrate includes:

forming a first active portion of a first transistor in the pixel arrangement area, where the first active portion includes a first metal oxide material;

forming a second active portion of a second transistor in the non-pixel arrangement area, where the second active portion includes a second metal oxide material different from the first metal oxide material, and a mobility of the second active portion is greater than a mobility of the first active portion.

Some embodiments of the present disclosure further provide a display panel including the above-mentioned array substrate.

### BRIEF DESCRIPTION OF THE DRAWINGS

In order to explain the technical solutions in the embodiments of the present disclosure more clearly, a brief introduction to the drawings required for the description of the embodiments is provided below. Apparently, the drawings in the following description are merely some embodiments of the present disclosure. For those skilled in the art, other drawings can be obtained from these drawings without any inventive effort.

In order to more fully understand the present disclosure and its beneficial effects, the following explanation will be provided in conjunction with the accompanying drawings, where the same reference numerals in the following descriptions represent the same components.

FIG. 1 is a schematic planar structural diagram of an array substrate according to some embodiments of the present disclosure.

FIG. 2 is a schematic structural diagram of a first transistor according to some embodiments of the present disclosure.

FIG. 3 is a schematic structural diagram of a second transistor according to some embodiments of the present disclosure.

FIG. 4 is another schematic structural diagram of the first transistor according to some embodiments of the present disclosure.

FIG. 5 is another schematic structural diagram of the second transistor according to some embodiments of the present disclosure.

FIG. 6 is a first schematic structural diagram of the array substrate according to some embodiments of the present disclosure.

FIG. 7 is a second schematic structural diagram of the array substrate according to some embodiments of the present disclosure.

FIG. 8 is a third schematic structural diagram of the array substrate according to some embodiments of the present disclosure.

FIG. 9 is a flowchart of a method for manufacturing an array substrate according to some embodiments of the present disclosure.

FIG. 10 is a schematic structural diagram of the array substrate in a manufacturing process of the array substrate according to some embodiments of the present disclosure.

FIG. 11 is a schematic structural diagram of a display panel according to some embodiments of the present disclosure.

### Reference Numerals:

10, first semiconductor layer; 11, first active portion; 111, first channel; 112, first portion to be doped; 113, second portion to be doped; 101, pixel arrangement area; 102, non-pixel arrangement area; and 1021, driving circuit sub-area;

20, second semiconductor layer; 21, second active portion; 211, second channel; 212, third portion to be doped; and 213, fourth portion to be doped;

30, first conductive layer; 31, first gate; and 32, second gate;

40, second conductive layer; 41, first source; 42 first drain; 43, second source; and 44, second drain;

50, light-shielding layer; 51, first light-shielding portion; and 52, second light-shielding portion;

60, substrate;

711, first buffer layer; 712, first gate insulating layer; 713, first interlayer dielectric layer; 714, first covering layer; 715, third buffer layer; and 716, third covering layer;

721, second buffer layer; 722, second gate insulating layer; 723, second interlayer dielectric layer; 724, second covering layer; 725, fourth buffer layer; and 726, fourth covering layer;

81/91, first insulating layer; 82/92, second insulating layer; 83/93, third insulating layer; 84, buffer layer; and 85, covering layer; and

90, display panel; and 900, array substrate.

### DETAILED DESCRIPTION

Technical solutions in the embodiments of the present disclosure will be clearly and completely described with reference to the drawings. Apparently, the described embodiments are only part of the embodiments of the present disclosure, not all of them. According to the embodiments in the present disclosure, all other embodiments obtained by those skilled in the art without any creative effort shall fall within the protection scope of the present disclosure.

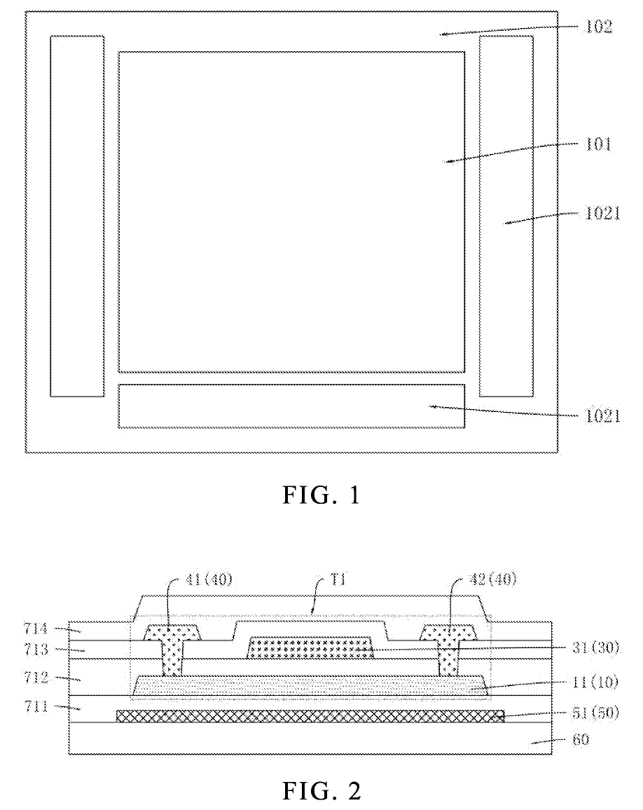

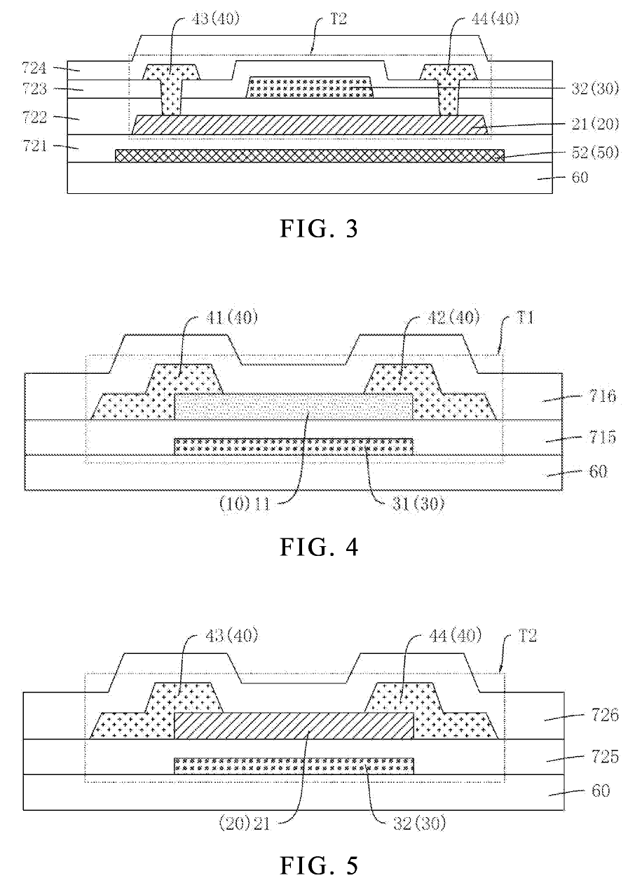

Referring to FIG. 1, FIG. 2, and FIG. 3, some embodiments of the present disclosure provide an array substrate including a pixel arrangement area 101 and a non-pixel arrangement area 102 adjacent to the pixel arrangement area 101. The array substrate further includes a first transistor T1 disposed in the pixel arrangement area 101 and a second transistor T2 disposed in the non-pixel arrangement area 102.

The first transistor T1 includes a first active portion 11, and the second transistor T2 includes a second active portion 21. The first active portion 11 includes a first metal oxide material, the second active portion 21 includes a second metal oxide material different from the first metal oxide material, and a mobility of the second active portion 21 is greater than a mobility of the first active portion 11.

In the application process of the embodiments of the present disclosure, the first transistor T1 is provided in the pixel arrangement area 101 and the second transistor T2 is provided in the non-pixel arrangement area 102, the first metal oxide material of the first active portion 11 of the first transistor T1 and the second metal oxide material of the second active portion 21 of the second transistor T2 are different metal oxide materials, and the mobility of the second active portion 21 is greater than the mobility of the first active portion 11, so that the stability of the first transistor T1 in the pixel arrangement area 101 and the charging efficiency of the second transistor T2 in the non-pixel arrangement area 102 can be simultaneously satisfied.

Specifically, referring to FIG. 1, FIG. 2, and FIG. 3, the non-pixel arrangement area 102 includes a driving circuit sub-area 1021, a plurality of pixel circuits are provided in the pixel arrangement area 101, and functional circuits, signal traces, and other devices may be provided in the non-pixel arrangement area 102. For example, the functional circuits, such as a GOA and a multiplexing circuit, may be provided in the driving circuit sub-area 1021 in the non-pixel arrangement area 102.

The array substrate is provided with a plurality of thin film transistors, and the plurality of thin film transistors may be distributed in the pixel circuit and the functional circuits, such as the GOA and the multiplexing circuit.

In some embodiments, the array substrate includes the first transistor T1 and the second transistor T2. The first transistor T1 includes the first active portion 11, a first gate 31, a first source 41, and a first drain 42. The second transistor T2 includes the second active portion 21, a second gate 32, a second source 43, and a second drain 44.

Both the first active portion 11 and the second active portion 21 include metal oxides, so that both the first transistor T1 and the second transistor T2 have small leakage current and good stability.

Furthermore, the mobility of the second active portion 21 is greater than the mobility of the first active portion 11, and thus the charging rate or charging efficiency of the second transistor T2 is greater than the charging rate or charging efficiency of the first transistor T1. That is, when the second active portion 21 is made of a metal oxide semiconductor material with a high mobility, and the first active portion 11 is made of a metal oxide semiconductor material with a mobility lower than the metal oxide semiconductor material of the second active portion 21, it can be achieved that the first transistor T1 has high stability and the second transistor T2 has high charging efficiency at the same time.

In the embodiments of the present disclosure, the first transistor T1 is disposed in the pixel arrangement area 101, and the second transistor T2 is disposed in the driving circuit sub-area 1021. That is, the pixel circuit includes the first transistor T1, and both the GOA and the multiplexing circuit include the second transistors T2, thereby achieving high stability of the thin film transistor in the pixel circuit and high charging efficiency of the thin film transistors in the GOA and the multiplexing circuit.

It should be noted that a low-temperature polycrystalline silicon active layer is generally prepared by crystallization and multiple times of ion injection processes, and both crystallization and ion injection processes need to be implemented by corresponding equipment. Therefore, compared with the preparation of the low-temperature polycrystalline silicon active layer, the second active portion 21 provided in the embodiments of the present disclosure can be prepared from the metal oxide material with high mobility, effectively reducing the process cost and reducing the amount of the process steps while achieving high mobility of the active layer.

In some embodiments, the array substrate further includes scanning signal lines, one end of the scanning signal line is connected to the GOA, the other end of the scanning signal line extends into the pixel arrangement area 101 and is connected to the pixel circuit. The GOA includes an output transistor connected to the scanning signal line, and at least an output transistor of the GOA is the second transistor T2 to satisfy the signal output efficiency of the output transistor. Furthermore, all thin film transistors of the GOA may be the second transistors T2. For example, the GOA may include a pull-up control module, a pull-up module, a pull-down module, and a pull-down maintenance module, and thin film transistors of the pull-up control module, thin film transistors of the pull-up module, thin film transistors of the pull-down module, and thin film transistors of the pull-down maintenance module may all be the second transistors T2.

In some embodiments, a ratio of the mobility of the second active portion 21 to the mobility of the first active portion 11 is greater than or equal to 2.

In some embodiments, the first metal oxide material of the first active portion 11 includes an indium gallium zinc oxide (IGZO), and the mobility of the first active portion 11 may be about 10 cm²/V·s. The second metal oxide material of the second active portion 21 includes at least one of an indium gallium zinc tin oxide (IGZTO), an indium tin oxide (IGO), a metal oxide doped with a lanthanide rare earth element (i.g. LnIZO), an indium gallium tin oxide (IGTO), or an indium zinc tin oxide (IZTO), and the mobility of the second active portion 21 may be greater than or equal to 20 cm²/V·s. Furthermore, the mobility of the second active portion 21 may be greater than or equal to 30 cm²/V·s and less than or equal to 50 cm²/V·s, for example, 30 cm²/V·s, 35 cm²/V·s, 40 cm²/V·s, 45 cm²/V·s, or 50 cm²/V·s.

Furthermore, the description will be provided below in conjunction with structures of the thin film transistors in different areas.

In some embodiments, referring to FIG. 1 and FIG. 2, the array substrate in the pixel arrangement area 101 includes a substrate 60, a first light-shielding portion 51 disposed on the substrate 60, a first buffer layer 711 disposed on the substrate 60 and covering the first light-shielding portion 51, the first active portion 11 disposed on the first buffer layer 711 away from the first light-shielding portion 51, a first gate insulating layer 712 disposed on the first buffer layer 711 and covering the first active portion 11, the first gate 31 disposed on the first gate insulating layer 712 away from the first active portion 11, a first interlayer dielectric layer 713 disposed on the first gate insulating layer 712 and covering the first gate 31, the first source 41 and the first drain 42 disposed on the first interlayer dielectric layer 713, and a first covering layer 714 disposed on the first interlayer dielectric layer 713 and covering the first source 41 and the first drain 42. The first source 41 and the first drain 42 respectively pass through the first interlayer dielectric layer 713 and the first gate insulating layer 712, and are connected to two sides of the first active portion 11.

In some embodiments, referring to FIG. 1 and FIG. 3, in the driving circuit sub-area 1021 of the non-pixel arrangement area 102, the array substrate includes the substrate 60, a second light-shielding portion 52 disposed on the substrate 60, a second buffer layer 721 disposed on the substrate 60 and covering the second light-shielding portion 52, the second active portion 21 disposed on the second buffer layer 721 away from the second light-shielding portion 52, a second gate insulating layer 722 disposed on the second buffer layer 721 and covering the second active portion 21, the second gate 32 disposed on the second gate insulating layer 722 away from the second active portion 21, a second interlayer dielectric layer 723 disposed on the second gate insulating layer 722 and covering the second gate 32, the second source 43 and the second drain 44 disposed on the second interlayer dielectric layer 723, and a second covering layer 724 disposed on the second interlayer dielectric layer 723 and covering the second source 43 and the second drain 44. The second source 43 and the second drain 44 respectively pass through the second interlayer dielectric layer 723 and the second gate insulating layer 722, and are connected to two sides of the second active portion 21.

It can be understood that the structure of film layers of the first transistor T1 in the pixel arrangement area 101 and the structure of film layers of the second transistor T2 in the non-pixel arrangement area 102 are respectively described in the above-mentioned embodiments. Since the pixel arrangement area 101 and the non-pixel arrangement area 102 are different areas of the array substrate, the structure of the film layers of the first transistor T1 and the structure of the film layers of the second transistor T2 may be partially the same. For example, the first buffer layer 711 and the second buffer layer 721 may be in the same layer, the first light-shielding portion 51 and the second light-shielding portion 52 may be in the same layer, the first gate insulating layer 712 and the second gate insulating layer 722 may be in the same layer, the first gate 31 and the second gate 32 may be in the same layer, the first source 41, the first drain 42, the second source 43, and the second drain 44 may be in the same layer, and the first covering layer 714 and the second covering layer 724 may be in the same layer.

In some embodiments, in the array substrate illustrated in FIG. 2 and FIG. 3, conductive treatments of the first active portion 11 and the second active portion 21 may be individually performed by an ion injection process, and the first gate 31 and the second gate 32 are respectively used as barrier layers. Therefore, short channels may be respectively formed in the first active portion 11 and the second active portion 21 to further improve the charging efficiency of the first transistor T1 and the charging efficiency of the second transistor T2. Ions injected in the ion injection process may be B ions, Ne ions, P ions, Ar ions, or the like, and the injected ions have a concentration of about 1E15 cm⁻³. The type and the concentration of the ions can be selected according to actual requirements, and are not limited herein.

It should be noted that, both the first transistor T1 and the second transistor T2 provided in the above-mentioned embodiments have a top gate structure. However, both the first transistor T1 and the second transistor T2 may have a bottom gate structure, as detailed below.

In some embodiments, referring to FIG. 1, FIG. 4, and FIG. 5, the array substrate in the pixel arrangement area 101 includes the substrate 60, the first gate 31 disposed on the substrate 60, a third buffer layer 715 disposed on the substrate 60 and covering the first gate 31, the first active portion 11 disposed on a side of the third buffer layer 715 away from the first gate 31, the first source 41 and the first drain 42 disposed on the first active portion 11 and the third buffer layer 715, and a third covering layer 716 covering the first source 41 and the first drain 42.

The array substrate in the non-pixel arrangement area 102 includes the substrate 60, the second gate 32 disposed on the substrate 60, a fourth buffer layer 725 disposed on the substrate 60 and covering the second gate 32, the second active portion 21 disposed on a side of the fourth buffer layer 725 away from the second gate 32, the second source 43 and the second drain 44 disposed on the second active portion 21 and the fourth buffer layer 725, and a fourth covering layer 726 covering the second source 43 and the second drain 44.

It can be understood that, the structure of the film layers of the first transistor T1 in the pixel arrangement area 101 and the structure of the film layers of the second transistor T2 in the non-pixel arrangement area 102 are respectively described in the above-mentioned embodiments. Since the pixel arrangement area 101 and the non-pixel arrangement area 102 are different areas of the array substrate, the structure of the film layers of the first transistor T1 and the structure of the film layers of the second transistor T2 may be partially the same. For example, the third buffer layer 715 and the fourth buffer layer 725 may be in the same layer, the first gate 31 and the second gate 32 may be in the same layer, the first source 41, the first drain 42, the second source 43, and the second drain 44 may be in the same layer, and the third covering layer 716 and the fourth covering layer 726 may be in the same layer.

It should be noted that, in the above-mentioned embodiments, part of the film layers of the first transistor T1 and part of the film layers of the second transistor T2 may be prepared from the same film layer or belong to the same film layer, so as to reduce the amount of the process steps and reduce the process cost.

Corresponding relationships between the structure of the film layers of the first transistor T1 and the structure of the film layers of the second transistor T2 will be described in detail with reference to specific embodiments below.

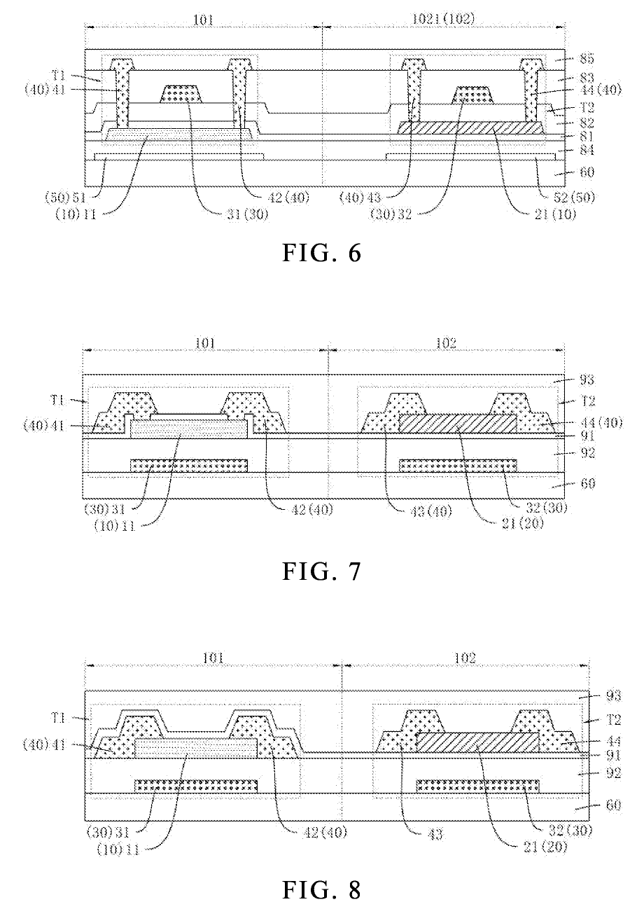

Referring to FIG. 1 and FIG. 6, in a specific embodiment, the array substrate includes the substrate 60, a light-shielding layer 50 disposed on the substrate 60, a buffer layer 84 disposed on the substrate 60 and covering the light-shielding layer 50, a first semiconductor layer 10 disposed on the buffer layer 84, a first insulating layer 81 disposed on the buffer layer 84 and covering the first semiconductor layer 10, a second semiconductor layer 20 disposed on the first insulating layer 81, a second insulating layer 82 disposed on the first insulating layer 81 and covering the second semiconductor layer 20, a first conductive layer 30 disposed on the second insulating layer 82, a third insulating layer 83 disposed on the second insulating layer 82 and covering the first conductive layer 30, a second conductive layer 40 disposed on the third insulating layer 83, and a covering layer 85 disposed on the third insulating layer 83 and covering the second conductive layer 40.

The light-shielding layer 50 includes the first light-shielding portion 51 disposed in the pixel arrangement area 101 and the second light-shielding portion 52 disposed in the driving circuit sub-area 1021.

The first semiconductor layer 10 includes the first active portion 11 disposed on a side of the buffer layer 84 away from the first light-shielding portion 51 and located in the pixel arrangement area 101.

The second semiconductor layer 20 includes the second active portion 21 disposed on a side of the first insulating layer 81 away from the second light-shielding portion 52 and located in the driving circuit sub-area 1021.

In the embodiments, both the first active portion 11 and the second active portion 21 include metal oxides, so that both the first transistor T1 and the second transistor T2 have small leakage current and better stability.

Moreover, the mobility of the second active portion 21 is greater than the mobility of the first active portion 11, and thus the charging rate or charging efficiency of the second transistor T2 is greater than the charging rate or charging efficiency of the first transistor T1. That is, when the second active portion 21 is made of a metal oxide semiconductor material with a high mobility, and the first active portion 11 is made of a metal oxide semiconductor material with a mobility lower than the metal oxide semiconductor material of the second active portion 21, it can be achieved that the first transistor T1 has high stability and the second transistor T2 has high charging efficiency.

In the embodiments of the present disclosure, the first transistor T1 is disposed in the pixel arrangement area 101, and the second transistor T2 is disposed in the driving circuit sub-area 1021. That is, the pixel circuit includes the first transistor T1, and both the GOA and the multiplexing circuit include the second transistors T2, thereby achieving high stability of the thin film transistor of the pixel circuit and high charging efficiency of the thin film transistors of the GOA and the multiplexing circuit.

The first conductive layer 30 includes the first gate 31 disposed on a side of the second insulating layer 82 away from the first active portion 11 and the second gate 32 disposed on a side of the second insulating layer 82 away from the second active portion 21. The first gate 31 is disposed in the pixel arrangement area 101, and the second gate 32 is disposed in the driving circuit sub-area 1021.

The second conductive layer 40 includes the first source 41, the first drain 42, the second source 43, and the second drain 44 disposed on a side of the third insulating layer 83 away from the second insulating layer 82. The first source 41 and the first drain 42 are disposed in the pixel arrangement area 101, and are connected to the first active portion 11 passing through the first insulating layer 81, the second insulating layer 82, and the third insulating layer 83. The second source 43 and the second drain 44 are disposed in the non-pixel arrangement area 101, and are connected to the second active portion 21 passing through the second insulating layer 82 and the third insulating layer 83.

The first insulating layer 81 is disposed between the first semiconductor layer 10 and the second semiconductor layer 20, and the second insulating layer 82 is disposed on a side of the second semiconductor layer 20 away from the first insulating layer 81 and between the second semiconductor layer 20 and the first conductive layer 30.

Since different materials are used to form the first active portion 11 and the second active portion 21 of the embodiments of the present disclosure, the first active portion 11 and the second active portion 21 are disposed in different semiconductor film layers, and the first insulating layer 81 can be used to separate the first semiconductor layer 10 and the second semiconductor layer 20. In addition, the second insulating layer 82 is provided to separate the first conductive layer 30 and the second semiconductor layer 20. Therefore, in the embodiments, the first insulating layer 81 is disposed between the first semiconductor layer 10 and the second semiconductor layer 20, and the second insulating layer 82 is disposed on a side of the second semiconductor layer 20 away from the first semiconductor layer 10, that is, the first insulating layer 81 and the second insulating layer 82 are provided between the first gate 31 and the first active portion 11. Furthermore, in order to prevent a distance between the first gate 31 and the first active portion 11 from being too large, in some embodiments, a thickness of the first insulating layer 81 is less than a thickness of the second insulating layer 82, so that the distance between the first gate 31 and the first active portion 11 can be reduced by reducing the thickness of the first insulating layer 81, thereby achieving effective turn-on and turn-off of the first transistor T1.

Referring to FIG. 1 and FIG. 7, in another specific embodiment, the array substrate includes the substrate 60, a first conductive layer 30 disposed on the substrate 60, a second insulating layer 92 disposed on the substrate 60 and covering the first conductive layer 30, a first semiconductor layer 10 disposed on the second insulating layer 92, a first insulating layer 91 disposed on the second insulating layer 92 and covering the first semiconductor layer 10, a second semiconductor layer 20 disposed on the first insulating layer 91 and the second semiconductor layer 20, a second conductive layer 40 disposed on the first insulating layer 91 and the second semiconductor layer 20, and a third insulating layer 93 covering the second conductive layer 40.

The first conductive layer 30 is disposed between the substrate 60 and the second insulating layer 92, and the first conductive layer 30 includes the first gate 31 disposed in the pixel arrangement area 101 and the second gate 32 disposed in the driving circuit sub-area 1021.

The first semiconductor layer 10 includes the first active portion 11 disposed on a side of the second insulating layer 92 away from the first gate 31, and the first active portion 11 is disposed in the pixel arrangement area 101.

The second semiconductor layer 20 includes the second active portion 21 disposed on a side of the first insulating layer 91 away from the second gate 32, and the second active portion 21 is disposed in the driving circuit sub-area 1021.

In the embodiments, both the first active portion 11 and the second active portion 21 include metal oxides, so that both the first transistor T1 and the second transistor T2 have small leakage current and better stability.

Furthermore, the mobility of the second active portion 21 is greater than the mobility of the first active portion 11, and thus the charging rate or charging efficiency of the second transistor T2 is greater than the charging rate or charging efficiency of the first transistor T1. That is, when the second active portion 21 is made of a metal oxide semiconductor material with a high mobility, and the first active portion 11 is made of a metal oxide semiconductor material with a mobility lower than the metal oxide semiconductor material of the second active portion 21, it can be achieved that the first transistor T1 has high stability and the second transistor T2 has high charging efficiency.

In the embodiments of the present disclosure, the first transistor T1 is disposed in the pixel arrangement area 101, and the second transistor T2 is disposed in the driving circuit sub-area 1021. That is, the pixel circuit includes the first transistor T1, and both the GOA and the multiplexing circuit include the second transistors T2, thereby achieving high stability of the thin film transistor of the pixel circuit and high charging efficiency of the thin film transistors of the GOA and the multiplexing circuit.

The second conductive layer 40 includes the first source 41, the first drain 42, the second source 43, and the second drain 44 disposed on a side of the first insulating layer 91 away from the second insulating layer 92. The first source 41 and the first drain 42 are disposed in the pixel arrangement area 101, and are connected to the first active portion 11 passing through the first insulating layer 81. The second source 43 and the second drain 44 are disposed in the non-pixel arrangement area 101 and connected to the second active portion 21.

The first insulating layer 91 is disposed between the first semiconductor layer 10 and the second semiconductor layer 20. The second insulating layer 92 is disposed on a side of the first semiconductor layer 10 away from the first insulating layer 91 and between the first semiconductor layer 10 and the first conductive layer 30.

Since different materials are used to form the first active portion 11 and the second active portion 21 of the embodiments of the present disclosure, the first active portion 11 and the second active portion 21 are disposed in different semiconductor film layers, and the first insulating layer 91 can be used to separate the first semiconductor layer 10 and the second semiconductor layer 20. In addition, the second insulating layer 92 is provided to separate the first conductive layer 30 and the first semiconductor layer 10, that is, the first insulating layer 91 and the second insulating layer 92 are provided between the second gate 32 and the second active portion 21. Furthermore, in order to prevent a distance between the second gate 32 and the second active portion 21 from being too large, in some embodiments, a thickness of the first insulating layer 91 is less than a thickness of the second insulating layer 92, so that the distance between the second gate 32 and the second active portion 21 can be reduced by reducing the thickness of the first insulating layer 91, thereby achieving effective turn-on and turn-off of the first transistor T1.

Referring to FIG. 1 and FIG. 8, the embodiments illustrated in FIG. 8 differ from the embodiments illustrated in FIG. 7 are in that the second conductive layer 40 is disposed on the second insulating layer 92 and covered by the first insulating layer 91, and the second conductive layer 40 includes the first source 41 and the first drain 42 connected to the first active portion 11.

The second source 43 and the second drain 44 are disposed on a side of the first insulating layer 91 away from the second insulating layer 92, and are respectively connected to two sides of the second active portion 21.

As described above, in the embodiments of the present disclosure, the first transistor T1 in the pixel arrangement area 101 and the second transistor T2 in the driving circuit sub-area 1021 are provided, both the first active portion 11 of the first transistor T1 and the second active portion 21 of the second transistor T2 include metal oxides, and the mobility of the second active portion 21 is greater than the mobility of the first active portion 11, and thus the stability of the first transistor T1 in the pixel arrangement area 101 and the charging efficiency of the second transistor T2 in the driving circuit sub-area 1021 can be simultaneously satisfied. Moreover, by providing part of the film layers of the first transistor T1 and the second transistor T2 prepared from the same film layer of the array substrate, the amount of the process steps can be reduced and the process cost can be reduced.

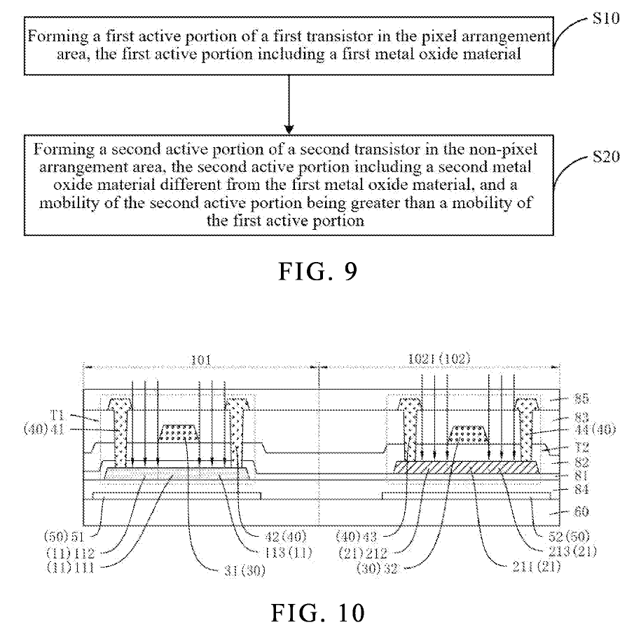

Furthermore, referring to FIG. 9 and FIG. 10, some embodiments of the present disclosure provide a method for manufacturing an array substrate, the array substrate includes a pixel arrangement area 101 and a non-pixel arrangement area 102 adjacent to the pixel arrangement area, and the method for manufacturing the array substrate includes steps S10 and S20 as follows.

In step S10, a first active portion 11 of a first transistor T1 is formed in the pixel arrangement area 101. The first active portion 11 includes a first metal oxide material.

In step S20, a second active portion 21 of a second transistor T2 is formed in the non-pixel arrangement area 102. The second active portion 21 includes a second metal oxide material different from the first metal oxide material, and a mobility of the second active portion 21 is greater than a mobility of the first active portion 11.

Specifically, in step S10, a substrate 60 is provided, and a light-shielding layer 50 is formed on the substrate 60. The light-shielding layer 50 includes a first light-shielding portion 51 disposed in the pixel arrangement area 101 and a second light-shielding portion 52 disposed in the non-pixel arrangement area 102.

Subsequently, a buffer layer 84 covering the first light-shielding portion 51 and the second light-shielding portion 52 is formed on the substrate 60.

Then, a first semiconductor layer 10 is formed on a side of the buffer layer 84 away from the substrate 60. The first semiconductor layer 10 includes the first active portion 11 of the first transistor T1, and the first active portion 11 includes the first metal oxide material.

In some embodiments, the first metal oxide material includes IGZO.

Subsequently, a first insulating layer 81 covering the first active portion 11 is formed on a side of the first semiconductor layer 10 away from the buffer layer 84.

In step S20, a second semiconductor layer 20 is formed on a side of the first insulating layer 81 away from the first semiconductor layer 10. The second semiconductor layer 20 includes the second active portion 21 of the second transistor T2, the second active portion 21 includes the second metal oxide material, and the mobility of the second active portion 21 is greater than the mobility of the first active portion 11.

In some embodiments, the second metal oxide material includes at least one of IGZTO, IGO, LnIZO, IGTO, or IZTO.

A second insulating layer 82 covering the second active layer 21 is formed on the first insulating layer 81.

Then, a first conductive layer 30 is formed on a side of the second semiconductor layer 20 away from the first semiconductor layer 10.

Specifically, the first conductive layer 30 is formed on a side of the second insulating layer 82 away from the second semiconductor layer 20. The first conductive layer 30 includes a first gate 31 of the first transistor T and a second gate 32 of the second transistor T2. The first gate 31 is disposed on a side of the first active portion 11 away from the substrate 60. The second gate 32 is disposed on a side of the second active portion 21 away from the substrate 60. The first active portion 11 includes a first channel 111 aligned with the first gate 31, and a first portion to be doped 112 and a second portion to be doped 113 respectively connected to opposite sides of the first channel 111. The second active portion 21 includes a second channel 211 aligned with the second gate 32, and a third portion to be doped 212 and a fourth portion to be doped 213 respectively connected to opposite sides of the second channel 211.

Subsequently, a third insulating layer 83 covering the first gate 31 and the second gate 32 is formed on the second insulating layer 82.

A second conductive layer 40 is formed on the third insulating layer 83. The second conductive layer 40 includes a first source 41 and a first drain 42 disposed in the pixel arrangement area 101, and a second source 43 and a second drain 44 disposed in the non-pixel arrangement area 102. The first source 41 and the first drain 42 are connected to the first active portion 11 passing through the first insulating layer 81, the second insulating layer 82, and the third insulating layer 83. The second source 43 and the second drain 44 are connected to the second active portion 21 passing through the second insulating layer 82 and the third insulating layer 83.

A covering layer 85 is formed on a side of the third insulating layer 83 away from the second insulating layer 82. The covering layer 85 covers the first source 41, the first drain 42, the second source 43, and the second drain 44.

In some embodiments, the method for manufacturing the array substrate further includes steps as follows. The first portion to be doped 112, the second portion to be doped 113, the third portion to be doped 212, and the fourth portion to be doped 213 are individually performed a conductive treatment by an ion injection process and using the first gate 31 and the second gate 32 as barrier layers, respectively, so as to form short channels in the first active portion 11 and the second active portion 21, further improving the charging efficiency of the first transistor T1 and the charging efficiency of the second transistor T2.

It can be understood that the method for manufacturing the array substrate in the above-described embodiments is described with the first transistor T1 and the second transistor T2 as top gate structures. However, both the first transistor T1 and the second transistor T2 may have a bottom gate structure, as detailed below.

Specifically, referring to FIG. 1, FIG. 7, and FIG. 9, in step S10, the first conductive layer 30 is formed on the substrate 60, and the first conductive layer 30 includes the first gate 31 disposed in the pixel arrangement area 101 and the second gate 32 disposed in the non-pixel arrangement area 102.

Subsequently, a second insulating layer 92 covering the first gate 31 and the second gate 32 is formed on the substrate 60.

Then, the first semiconductor layer 10 is formed on the second insulating layer 92. The first semiconductor layer 10 includes the first active portion 11 formed on a side of the second insulating layer 92 away from the first gate 31, and the first active portion 11 includes the first metal oxide material.

A first insulating layer 91 covering the first active portion 11 is formed on the second insulating layer 92.

In step S20, the second semiconductor layer 20 is formed on the first insulating layer 91. The second semiconductor layer 20 includes the second active portion 21 formed on a side of the first insulating layer 91 away from the second gate 32, the second active portion 21 includes the second metal oxide material, and the mobility of the second active portion 21 is greater than the mobility of the first active portion 11.

Then, the second conductive layer 40 is formed on the first insulating layer 91 and the second semiconductor layer 20. The second conductive layer 40 includes the first source 41, the first drain 42, the second source 43, and the second drain 44. The first source 41 and the first drain 42 pass through the first insulating layer 91, and are respectively connected to opposite sides of the first active portion 11. The second source 43 and the second drain 44 are respectively connected to opposite sides of the second active portion 21.

A third insulating layer 93 is formed on the second conductive layer 40. The third insulating layer 93 covers the first source 41, the first drain 42, the second source 43, and the second drain 44.

In addition, in some embodiments of the present disclosure, referring to FIG. 1, FIG. 8, and FIG. 9, the embodiments illustrated in FIG. 8 differ from the embodiments illustrated in FIG. 7 are in that, after the first semiconductor layer 10 is formed, the second conductive layer 40 is formed on the first semiconductor layer 10, and the second conductive layer 40 includes the first source 41 and the first drain 42 respectively connected to opposite sides of the first active portion 11.

Then, the first insulating layer 91, which covers the first active portion 11, the first source 41, and the first drain 42, is formed.

In step S20, the second semiconductor layer 20 is formed on the first insulating layer 91. The second semiconductor layer 20 includes the second active portion 21 formed on a side of the first insulating layer 91 away from the second gate 32, the second active portion 21 includes the second metal oxide material, and the mobility of the second active portion 21 is greater than the mobility of the first active portion 11.

Then, the second source 43 and the second drain 44 are formed on the first insulating layer 91 and the second semiconductor layer 20. The second source 43 and the second drain 44 are respectively connected to opposite sides of the second active portion 21.

Subsequently, the third insulating layer 93 covering the second source 43 and the second drain 44 is formed on the second conductive layer 40.

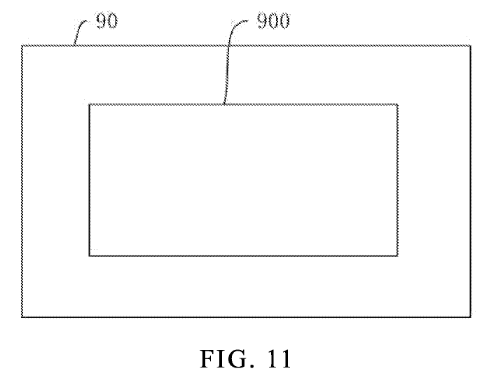

Referring to FIG. 11, some embodiments of the present disclosure further provide a display panel 90 including an array substrate 900, the array substrate 900 may be the array substrate as described in any one of the above-mentioned embodiments.

In some embodiments, the display panel 90 may be an organic light-emitting diode display panel, and thus the display panel 90 further includes film layers such as an anode layer, an organic light-emitting layer, a cathode layer, and an encapsulation layer disposed on the array substrate 900.

In some embodiments, the display panel 90 may be a liquid crystal display panel, and thus the display panel 90 further includes pixel electrodes disposed on the array substrate 900, a liquid crystal layer disposed on a side of the pixel electrodes away from the array substrate 900, a color filter substrate disposed on a side of the liquid crystal layer away from the array substrate 900, and common electrodes disposed on the array substrate 900 and/or the color filter substrate.

It can be understood that, since the display panel 90 includes the array substrate 900 having the same structure as the array substrate described in any one of the above-mentioned embodiments, the display panel 90 has the same beneficial effects as the array substrate described in any one of the above-mentioned embodiments, and will not be repeated here.

In the description of the present disclosure, the terms “first” and “second” are used merely for descriptive purposes and should not be construed as indicating or implying relative importance, nor as implicitly specifying the quantity of the technical features referred to. Therefore, the features defined as “first” and “second” may explicitly or implicitly include one or more features. In the description of the present disclosure, the terms “a plurality of” and “more” refer to two or more than two, unless otherwise specified.

In the above-mentioned embodiments, the description of each embodiment has its own emphasis, and for parts not described in detail in a certain embodiment, please refer to the relevant description of other embodiments.

The embodiments, implementations, and related technical features of the present disclosure can be combined and replaced with each other without conflict.

The above are merely preferred embodiments of the present disclosure, and do not limit the present disclosure in any form. Any simple modifications, equivalent changes, and modifications made to the above embodiments according to the technical essence of the present disclosure without departing from the contents of the technical solutions of the present disclosure still fall within the scope of the technical solutions of the present disclosure.

What is claimed is:

1. An array substrate comprising a pixel arrangement area and a non-pixel arrangement area adjacent to the pixel arrangement area, wherein the array substrate further comprises a first transistor disposed in the pixel arrangement area and a second transistor disposed in the non-pixel arrangement area; and
wherein the first transistor comprises a first active portion, the second transistor comprises a second active portion, the first active portion comprises a first metal oxide material, the second active portion comprises a second metal oxide material different from the first metal oxide material, and a mobility of the second active portion is greater than a mobility of the first active portion.

2. The array substrate according to claim 1, wherein the first metal oxide material comprises an indium gallium zinc oxide; and
wherein the second metal oxide material comprises at least one of an indium gallium zinc tin oxide, an indium tin oxide, a metal oxide doped with a lanthanide rare earth element, an indium gallium tin oxide, or an indium zinc tin oxide.

3. The array substrate according to claim 1, wherein the mobility of the second active portion is greater than or equal to 20 cm²/V·s.

4. The array substrate according to claim 1, wherein a ratio of the mobility of the second active portion to the mobility of the first active portion is greater than or equal to 2.

5. The array substrate according to claim 1, wherein the second active portion is disposed on a side of the first active portion, wherein the array substrate further comprises:
a first insulating layer disposed between the first active portion and the second active portion; and
a second insulating layer disposed on a side of the second active portion away from the first insulating layer, or disposed on a side of the first active portion away from the first insulating layer;
wherein a thickness of the first insulating layer is less than a thickness of the second insulating layer.

6. The array substrate according to claim 5, wherein the first transistor further comprises a first gate, and the second transistor further comprises a second gate; and
wherein the first gate is disposed on a side of the second insulating layer away from the first active portion, the second gate is disposed on a side of the second insulating layer away from the second active portion, and the first gate and the second gate are disposed in a same layer.

7. The array substrate according to claim 6, further comprising a substrate disposed on a side of the first active portion away from the first insulating layer, wherein the second insulating layer is disposed on a side of the second active portion away from the first insulating layer; and
wherein both the first gate and the second gate are disposed on a side of the second insulating layer away from the second active portion.

8. The array substrate according to claim 6, further comprising a substrate disposed on a side of the first active portion away from the first insulating layer, wherein the second insulating layer is disposed between the first active portion and the substrate; and
wherein both the first gate and the second gate are disposed between the substrate and the second insulating layer.

9. The array substrate according to claim 5, wherein the first transistor further comprises a first source and a first drain, and the second transistor further comprises a second source and a second drain; and
wherein all of the first source, the first drain, the second source, and the second drain are disposed in a same layer and located on a side of the second active portion away from the first active portion, the first source and the first drain are connected to the first active portion passing through the first insulating layer, and the second source and the second drain are connected to the second active portion.

10. The array substrate according to claim 1, wherein the non-pixel arrangement area comprises a driving circuit sub-area, and the array substrate comprises a pixel circuit disposed in the pixel arrangement area, and a gate driver on array (GOA) and a multiplexing circuit disposed in the driving circuit sub-area; and
wherein the pixel circuit comprises the first transistor, and the GOA and the multiplexing circuit each comprises the second transistor.

11. A method for manufacturing an array substrate, wherein the array substrate comprises a pixel arrangement area and a non-pixel arrangement area adjacent to the pixel arrangement area, and the method for manufacturing the array substrate comprises:
forming a first active portion of a first transistor in the pixel arrangement area, wherein the first active portion comprises a first metal oxide material;
forming a second active portion of a second transistor in the non-pixel arrangement area, wherein the second active portion comprises a second metal oxide material different from the first metal oxide material, and a mobility of the second active portion is greater than a mobility of the first active portion.

12. The method for manufacturing the array substrate according to claim 11, wherein the step of forming the first active portion of the first transistor in the pixel arrangement area comprises:
forming a first semiconductor layer comprising the first active portion on a side of a substrate; and
wherein the step of forming the second active portion of the second transistor in the non-pixel arrangement area comprises:
forming a second semiconductor layer comprising the second active portion on a side of the first semiconductor layer away from the substrate.

13. The method for manufacturing the array substrate according to claim 12, further comprising:
forming a first conductive layer on a side of the second semiconductor layer away from the first semiconductor layer, wherein the first conductive layer comprises a first gate of the first transistor and a second gate of the second transistor, the first gate is disposed on a side of the first active portion away from the substrate, and the second gate is disposed on a side of the second active portion away from the substrate, wherein the first active portion comprises a first channel aligned with the first gate, and a first portion to be doped and a second portion to be doped respectively connected to opposite sides of the first channel, and the second active portion comprises a second channel aligned with the second gate, and a third portion to be doped and a fourth portion to be doped respectively connected to opposite sides of the second channel; and
performing a conductive treatment on the first portion to be doped, the second portion to be doped, the third portion to be doped, and the fourth portion to be doped by an ion injection process.

14. A display panel comprising an array substrate comprising a pixel arrangement area and a non-pixel arrangement area adjacent to the pixel arrangement area, wherein the array substrate further comprises a first transistor disposed in the pixel arrangement area and a second transistor disposed in the non-pixel arrangement area; and
wherein the first transistor comprises a first active portion, the second transistor comprises a second active portion, the first active portion comprises a first metal oxide material, the second active portion comprises a second metal oxide material different from the first metal oxide material, and a mobility of the second active portion is greater than a mobility of the first active portion.

15. The display panel according to claim 14, wherein the first metal oxide material comprises an indium gallium zinc oxide; and
wherein the second metal oxide material comprises at least one of an indium gallium zinc tin oxide, an indium tin oxide, a metal oxide doped with a lanthanide rare earth element, an indium gallium tin oxide, or an indium zinc tin oxide.

16. The display panel according to claim 14, wherein the mobility of the second active portion is greater than or equal to 20 cm²/V·s.

17. The display panel according to claim 14, wherein a ratio of the mobility of the second active portion to the mobility of the first active portion is greater than or equal to 2.

18. The display panel according to claim 14, wherein the second active portion is disposed on a side of the first active portion, wherein the array substrate further comprises:
a first insulating layer disposed between the first active portion and the second active portion; and
a second insulating layer disposed on a side of the second active portion away from the first insulating layer, or disposed on a side of the first active portion away from the first insulating layer;
wherein a thickness of the first insulating layer is less than a thickness of the second insulating layer.

19. The display panel according to claim 18, wherein the first transistor further comprises a first gate, the second transistor further comprises a second gate, the first gate is disposed on a side of the second insulating layer away from the first active portion, the second gate is disposed on a side of the second insulating layer away from the second active portion, and the first gate and the second gate are disposed in a same layer; and
wherein the array substrate further comprises a substrate disposed on a side of the first active portion away from the first insulating layer, the second insulating layer is disposed on a side of the second active portion away from the first insulating layer, and both the first gate and the second gate are disposed on a side of the second insulating layer away from the second active portion.

20. The display panel according to claim 18, wherein the first transistor further comprises a first source and a first drain, and the second transistor further comprises a second source and a second drain; and
wherein all of the first source, the first drain, the second source, and the second drain are disposed in a same layer and located on a side of the second active portion away from the first active portion, the first source and the first drain are connected to the first active portion passing through the first insulating layer, and the second source and the second drain are connected to the second active portion.
